(19) United States
(12) Patent Application Publication
(10) Pub. No.: US 2026/0280533 A1
(43) Pub. Date: Sep. 17, 2026

(54) EFFICIENT PWM MODULATOR UTILIZING INTERPOLATION

(71) Applicant: Axign B.V., Enschede (NL)

(72) Inventors: Jelmer Bas KOSTERS, Enschede (NL); Christiaan Egidius LOKIN, Enschede (NL); Daniel SCHINKEL, Enschede (NL)

(21) Appl. No.: 19/168,803

(22) PCT Filed: Mar. 21, 2024
(86) PCT No.: PCT/NL2024/050138

§ 371 Date: Sep. 24, 2025

(30) Foreign Application Priority Data
Mar. 25, 2023 (NL) 2034425

(51) Int. Cl. H03K 3/017; H03K 5/14

(52) U.S. Cl. CPC H03K 3/017; H03K 5/14

(57) ABSTRACT

The present invention is in the field of basic electronic circuitry, in particular of a digital signal processor for streaming audio applications, more in particular a pulse-width modulator, an integrated circuit comprising said electronic circuit, and a device comprising said electronic circuitry or said integrated circuit, such as an audio device.

### FIELD OF THE INVENTION

The present invention is in the field of basic electronic circuitry, in particular of a digital signal processor for streaming audio applications, more in particular a pulse-width modulator, an integrated circuit comprising said electronic circuit, and a device comprising said electronic circuitry or said integrated circuit, such as an audio device.

### RELATED APPLICATIONS

The present application claims the benefit of priority from Dutch Patent Applications NL2034425, filed on Mar. 25, 2023, in the name of Axign IP B.V., Netherlands.

The entire contents of the above-referenced application and of all priority documents as referenced in any present or future Application Data Sheet filed herewith are hereby incorporated by reference for all purposes.

### BACKGROUND OF THE INVENTION

The present invention relates in an aspect to a digital controller that outputs pulse-width modulated (PWM) signals. It further relates to implementations that use feed-back of the output signal to correct for any errors. It further relates to an implementation where the feedback signal is derived from the output of an analog-to-digital converter (ADC), to create a ‘mixed-signal PWM controller’.

A primary application of such a controller is an audio amplifier, where the PWM signal can be used to drive a switching (class-D) amplifier. After the switching amplifier there is usually an output filter provided to remove high-frequency switching components and make a smooth output signal. Said output signal may be fed to a speaker. The ADC in such a controller is capable of measuring the signal directly at the speaker, i.e. after the output filter. The digital controller can subsequently be configured further e.g. to have a high loop gain to suppress non-idealities in the signal that may arise in the switching amplifier and the output filter.

Traditionally switching amplifiers used either no feedback at all, or they used analog feedback loops with a feedback taken before an output filter. These analog systems usually have only moderate filter complexity (most commonly a 2nd order loop-filter). This is found to result in less loop-gain and less suppression of non-idealities from the switching amplifier, and even no suppression at all for non-idealities that originate in the output filter.

An audio power amplifier comprises basic electronic circuitry that amplifies lowpower electronic audio signals that enter the circuitry, to a high enough power for driving a loudspeaker. Audio power amplifiers find many applications. The audio amplifier may be combined in a chain of electronic components or electronic circuits, each performing an individual task or contributing to a common task. Basically any audio signal can be provided to the power amplifier, as is commonly done. The output signal of the audio amplifier power may be from less than a few watts to tens or hundreds of watts, and sometimes even a multitude thereof. Power amplifiers are typically integrated in a (final) product or integrated circuit.

Design parameters for audio power amplifiers are amongst others frequency response, gain, noise, and distortion, which parameters are typically interdependent.

A Class-D amplifier is typically used in modern consumer electronics audio products, bass amplifiers and sound reinforcement system gear. Amplifiers may comprise filters, preamplifiers, power output stages and the like. An audio filter is typically a frequency dependent circuit. It is designed to operate in a specific audio frequency range. It is noted that a human hearing range is commonly considered to run from 20 to 20,000 Hz. There is however a considerable variation between individuals, especially at high frequencies. Also, typically there is a gradual loss of sensitivity to higher frequencies with age. In addition, sensitivity to specific frequencies may also vary with said frequency. The audio frequency range typically used in audio amplifiers therefore runs from about 20 Hz to 20 kHz, and sometimes to 40 kHz or even 100 kHz. Audio filters are designed to amplify, pass, or attenuate specific frequency ranges. Many types of filters exist, for instance low-pass filters, high-pass filters, band pass filters, all-pass filters effecting a phase of a given frequency component, etc.

Analog pulse-width modulators do not have the limitation of quantization steps, but are limited by typical analog demerits such as chip area, power consumption, offset, mismatch, etc. and require digital-to-analog conversion prior to the modulator. Digital pulse-width modulators can be very low power and easy to implement in digital ICs, but performance is strongly limited by quantization noise because of the limited time granularity imposed by the clock frequency of the system.

When a pulse-width modulator is used for applications where signal-to-noise ratios are critical, such as in a class-D amplifier, the PWM resolution is a limiting factor for the system performance. In previous art, the system clock frequency is increased to decrease the time steps and improve resolution. This comes at a big cost, as power consumption rises quickly as the clock frequency nears the technology limits.

FIG. 1 shows an exemplary prior art analog class-D system, either with feedback before or after (or both) the LC-filter. The analog pulse-width modulator is not limited in resolution, practically giving infinite granularity in the width of the pulse.

FIG. 2 shows an exemplary digital counterpart to this system, for use in ICs. The digital pulse-width modulator is limited in resolution, which results in a quantization noise source in the system.

A typical digital pulse-width modulator is shown in FIG. 3. A digital carrier (staircase) is generated by digital logic running on a system clock. This system clock frequency is limited by the capabilities of the CMOS technology.

In computing and electronic processing the clock rate, also referred to as clock speed, relates to a frequency ([Hz]) at which the clock generator of a processor can generate pulses. The pulses are typically used to synchronize the operations of various components. It is clearly an indication of the processor's speed. The clock rate over time gradually increased from kHz to GHz.

FIG. 4 shows the effects of quantization of the PWM signal with regards to the analog counterpart. A comparison of the input signal with a continuous triangle wave theoretically yields no error, but a discrete PWM carrier yields a quantization error resulting in a delay.

By increasing the carrier resolution, quantization errors can be reduced, as shown in FIG. 5. Quantization errors are shaped out of the audio band in implementations with feedback, but typically the error suppression is limited by a limited amount of loop-gain. Lower quantization noise will improve signal to noise ratios. Increasing clock frequencies to tens or hundreds of MHz is not always an attractive option because of power and area constraints on the chip.

Incidentally US 2004/222866 A1 recites a digital technique for pulse width modulation (PWM) utilizes a tapped delay line receiving a reference clock and generating a plurality of time delayed reference clock transitions having finer time resolution than the reference clock signal. A multiplexer receives the plurality of time delayed reference clock transitions as an input thereto and producing an output when one of the plurality of time delayed reference clock transitions is addressed. An accumulator circuit generates control timing signals associated with the input signal sampling rate Fsample that are used to select outputs from the delay line 304 representing a pulse width modulated output signal.

It is an objective of the present invention to overcome disadvantages of the prior art pulse-width modulators and amplifiers without jeopardizing functionality and advantages.

### SUMMARY OF THE INVENTION

In a first aspect the present invention relates to an electronic circuit (1) for pulse-width modulation comprising at least one clock generator (60) configured to provide an operational clock speed for a coarse time grid, in particular wherein the coarse time grid is provided to an input signal, at least one Digital Pulse-Width Modulator (DPWM) (10), the DPWM configured to receive input, and configured to provide output to at least one Delay-line (20) and to an Interpolator (30) of at least one interpolation circuit (100), wherein the at least one interpolation circuit (100) comprises at least one Delay-line (DL) (20) configured to provide output individually to at least one edge selector (4), wherein the DL comprises a delay controller (21) configured to control the delay of the at least one DL, and configured to provide output to at least one edge selector (40), at least one Interpolator (30) configured to receive input from the DPWM, from the digital carrier generator, and from an error signal from the digital PWM modulator and to provide interpolated output to at least one edge selector (40), wherein the interpolator (30) comprises a step-size detector configured to detect an increase in a carrier signal exceeding an input signal, and at least one edge selector (40) configured to provide time quantized PWM output, in particular wherein the quantization is provided at a frequency higher than of the at least one clock generator. There to the carrier signal and input signal are configured to “cross” or “intersect” one and another, and the step-size detector is configured to detect the change in the carrier signal when said carrier signal or intersects the input signal. In line with a detection of an increase, a decrease may be detected; “increase” or “decrease” effectively, within the context of the present circuit and the like, relate to a positive or negative sign of a signal or the like. The present electronic circuit may be used for low power amplifiers, such as down to 10 mW amplifiers, for headphones, e.g. consuming ~10 mW, for stereo systems, e.g. consuming ~1 kW, and for PA systems, motor control, RF systems, e.g. consuming ~1 MW. Therewith a pulse-width modulator is presented which utilizes interpolation to increase the effective resolution, which may be an on-chip PWM. On-chip pulse-width modulation (PWM) can be achieved both in analog and digital fashion. The present invention circumvents a need to increase the clock frequency of the system, by interpolating the coarse PWM signal. Interpolation is achieved by utilizing a delay-line and edge selection logic. The delay-line can be implemented by a DLL, or re-used from an already existing PLL, e.g. on the chip. The present invention is based on the pulse-width modulator such as shown in FIG. 3, and in addition provides an interpolation system. Interpolation is achieved by measuring the magnitude of the error between input signal and carrier signal, and calculating the required delay within one system clock cycle; which is by design the smallest digital time-step the carrier can make. As such, any type or form of carrier signal may be used. Further, it may be different in each (subsequent) clock cycle, or the same. This equivalent delay code is then used to select a specific edge from a delay-line which is in some way locked to the clock frequency of the pulse-width modulator (usually the same clock as the rest of the chip). This basic principle is shown in FIG. 6. The invention can be applied wherever digital pulse-width modulation is applied and the amount of quantization noise needs to be reduced. Most notably, this will include applications with relatively high speed PWM such as in audio applications, RF amplifiers, motor controllers, microcontrollers and such, where the normal clock resolution is not sufficient for good quality PWM. The present invention therewith uses relatively low amounts of power, and in terms of design, is simple. In an embodiment, similar to FIG. 2, the present invention relates in an aspect to a digital controller that outputs pulse-width modulated (PWM) signals. It further relates to implementations that use feed-back of the output signal to correct for any errors. It further relates to an implementation where the feedback signal is derived from the output of an analog-to-digital converter (ADC), to create a ‘mixed-signal PWM controller’.

The present electronic circuit can specifically ‘feed’ multiple PWM modulators with 1 delay-line (‘scalability for multiple channels of PWM on 1 chip, without unnecessary reuse of parts’). It does not rely on a ‘DLL’ specifically designed for the PWM modulator (like the prior art), but on a ‘PLL’ that initially provides the entire chip with a clock with a ‘coarse’ time grid (the ‘system clock’ may have a low frequency), making the entire chip relatively economical in power consumption. The delay line, which is deployed as a ‘Ring Oscillator’ in the PLL is then also used to select a PWM flank with a finer time grid. The PWM error signal ‘error’ (the difference between input and carrier), the coarse PWM signal ‘coarse pwm’, and the value of the carrier signal ‘carrier’, are available on the ‘coarse’ time grid. The ‘Interpolator’ also calculates on the coarse time grid which edge of the delay-line/ring-oscillator should be chosen by the ‘edge selector’ (see FIG. 13).

In the context of the present application the phrase “at least one” is considered to encompass first of all the option of “one”. In its simplest form elements identified occur only once. However, stacked structures, such as in Axign's AX5689 chip, may be considered. These stacked structures may be considered as parallel structures. Likewise serial structures may be considered. Therefore, the phrase “at least one” encompasses such more complex structures, in a way, multiplexed structures. The claims encompass the simples embodiment of the present invention.

The term “quantize” relates to a sub-division into quanta. Therefore quantization provides discrete values, also referred to as “quantum”. A quantum is any of a very small discrete increment that form small or the smallest units into which physical quantities can be sub-divided, and by which a value of a quantity (or parameter) increases or decreases. In the present invention the physical parameter that is quantized is time.

The present Delay-line locked loop, which is often referred to as a ‘delay locked loop’, is considered as only one of the implementation forms to control the delay of the delay line. Basically, a requirement for the delay-line is that the N delays are equal to one clock cycle, or part thereof, such where both edges of the clock are used, half a clock cycle. There are several ways to make the delay of the delay-line equal to a clock cycle, using a DLL being one of them. In the present implementation form, inventors also use the related PLL.

The present electronic circuit also relates in some aspects to elements referred to in the prior art, which may be combined with other aspects; the same applies to other aspects of the invention.

In a second aspect the present invention relates to a delay-line (20) for an electronic circuit, wherein the Delay-line (20) is configured to provide output individually to at least one edge selector (40), wherein the DL comprises a controller (21) configured to control the delay of the DL and configured to provide output to at least one edge selector (40).

In a further aspect the present invention relates to a Pulse-width interpolator (30) for an electronic circuit, wherein the interpolator (30) is configured to provide interpolated output to at least one edge selector (40) and to receive input from At least one Digital pulse-width modulator (DPWM) (10) and from an error signal from the digital PWM modulator and from a digital carrier generator 80, comprising a step-size detector configured to detect an increase in a carrier signal exceeding an input signal, and in particular a comparator configured for comparing the value of the carrier signal and the value of the input signal and providing an error signal, and a converter configured to convert the error signal into an integer value based on the number of quantized time grid elements and the error signal size and step-size.

In a further aspect the present invention relates to an integrated circuit comprisesing an electronic circuit according to the invention, or a delay-line (20) according to the invention, or an interpolator (30) according to the invention.

In a further aspect the present invention relates to an electronic device comprising an integrated circuit according to the invention or an electronic circuit according to the invention, in particular wherein the electronic device is a product, more in particular wherein the product is selected from an audio amplifier, an active loudspeaker system, an active noise reduction system, a high-speed closed loop controller, a high resolution low latency data converter, an A/D converter, a power supply controller, an RF amplifier, a motor controller, in particular a high speed motor controller, an industrial controller, a microcontroller, a digital audio converter, a digital amplifier controller, and combinations thereof.

Thereby the present invention provides a solution to one or more of the above mentioned problems.

Advantages of the present description are detailed throughout the description.

### DETAILED DESCRIPTION OF THE INVENTION

The present invention relates in a first aspect to an electronic circuit.

In an exemplary embodiment of the present electronic circuit the controller (21) is configured to provide a delay locked loop with a DL fine time grid, which DL fine time grid is N times smaller than the coarse time grid of the at least one clock generator, in particular wherein N∈[2,2¹⁰]. In other words, the coarse time grid is provided to be quantized into a fine time grid, with quanta N times smaller than that of the coarse time grid, as provided by the clock generator.

In an exemplary embodiment of the present electronic circuit the at least one DL (20) is selected from an analog delay-line and a digital delay line, in particular an analog delay line.

In an exemplary embodiment of the present electronic circuit the at least one DL (20) is controlled by a locked loop selected from a delay locked loop (DLL) (35) and from a Phase Locked Loop (PLL) (36).

In an exemplary embodiment of the present electronic circuit the at least one DL (20) is part of a DLL (35), and wherein the DLL (35) comprises a Phase Frequency Detector (PFD) (26) configured to receive input from the at least one clock generator (60) and from the DL (20), a Loop Filter (27) configured to receive input from the PFD and to provide output to the at least one DL (20).

In an exemplary embodiment of the present electronic circuit the at least one DL (20) is part of a PLL (36), wherein the PLL (36) comprises a Phase Frequency Detector (PFD) (26) configured to receive input from the at least one clock generator (60) and from the DL (20), a Loop Filter (27) configured to receive input from the PFD and to provide output to the at least one DL (20), in particular wherein the at least one DL's output is configured to feed back to its input therewith forming at least one oscillator (21a), in particular at least one n-stage ring-oscillator.

In an exemplary embodiment of the present electronic circuit the at least one oscillator (21a) and the at least one clock generator (60) are one and the same.

In an exemplary embodiment the present electronic circuit comprises 2-M DPWMs (10), in particular wherein M∈[2,2⁶].

In an exemplary embodiment the present electronic circuit comprises one DL (20). In an exemplary embodiment the present electronic circuit comprises one edge selector (40).

In an exemplary embodiment of the present electronic circuit the at least one interpolator (30) comprises a step-size detector configured to detect an increase in a carrier signal exceeding an input signal, a comparator configured for comparing the value of the carrier signal and the value of the input signal and providing an error signal, and a converter configured to convert the error signal into an integer value based on the number of quantized time grid elements and the error signal size and step-size.

In an exemplary embodiment of the present electronic circuit the at least one clock generator (60) is configured to provide an operational clock speed of 5 MHz-20 GHz, in particular 10 MHz-5 GHz, more in particular 30 MHz-1 GHz, even more in particular 50 MHz100 MHz.

In an exemplary embodiment the present electronic circuit further comprises at least one digital carrier generator (80) configured to receive input from the at least one clock generator (60), and at least one adder (90), configured to receive input from the at least one digital carrier generator (80) and to provide output to the at least one Digital pulse-width modulator (DPWM) (10) and to the at least one Interpolator (30), in particular wherein each individual digital carrier generator is configured to provide output to a multitude of DWPMs and/or interpolators, in particular wherein a multitude is 2-2¹⁰, such as 2²−2³.

The invention although described in detailed explanatory context may be best understood in conjunction with the accompanying examples and figures.

### SUMMARY OF FIGURES

FIG. 1-15 show details of the present digital signal processor and aspects thereof.

### DETAILED DESCRIPTION OF FIGURES

The figures are of an exemplary nature. Elements of the figures may be combined. In the figures:
1 Electronic circuit
10 Digital Pulse-width Modulator
20 Delay line
21 controller
21a oscillator
26 phase frequency detector
27 loop filter
30 PWM interpolator
35 delay locked loop
36 phase locked loop
40 edge selector
60 clock generator
80 digital carrier generator
90 adder
100 interpolation circuit

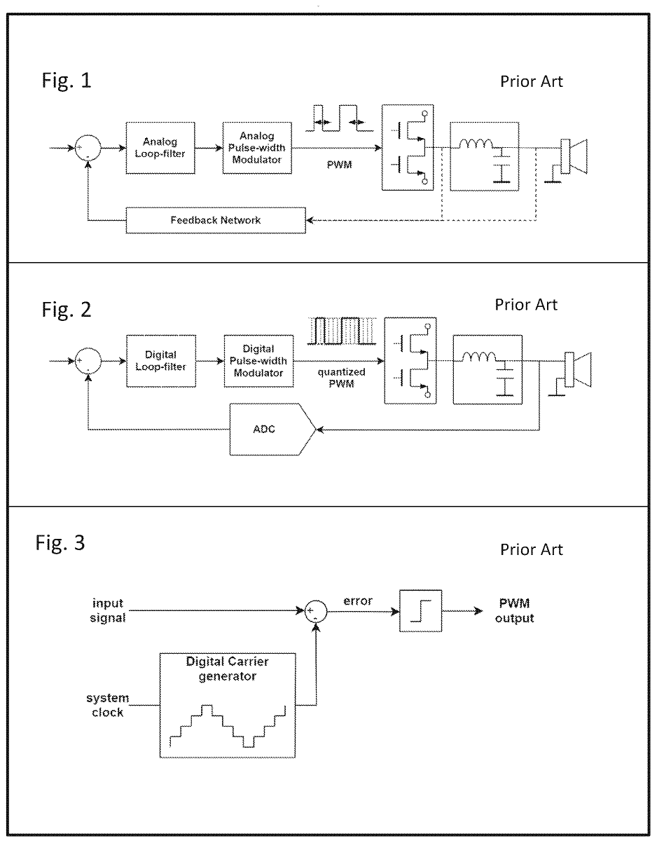

FIG. 1 shows a typical implementation of an analog class-D amplifier.

FIG. 2 shows an Axign digital class-D amplifier.

FIG. 3 shows a typical pulse-width modulator.

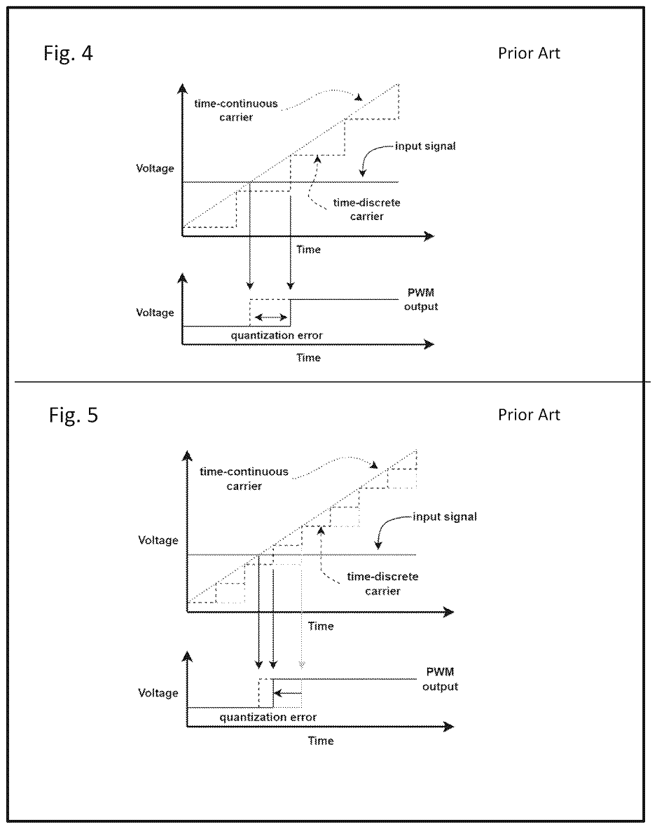

FIG. 4 shows a comparison of a time-continuous and time-discrete carrier for generating a PWM signal.

FIG. 5 shows effects on PWM delay error when increasing digital PWM resolution.

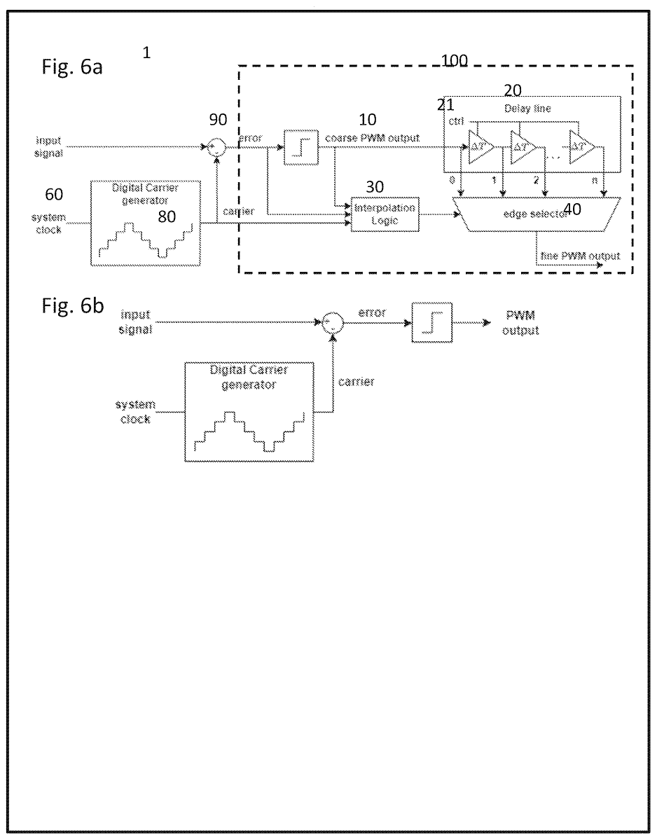

FIG. 6a,b shows a Digital pulse-width modulator with added interpolation system. It is further clarified that digital carrier generator is configured to provide carrier output to interpolator 30.

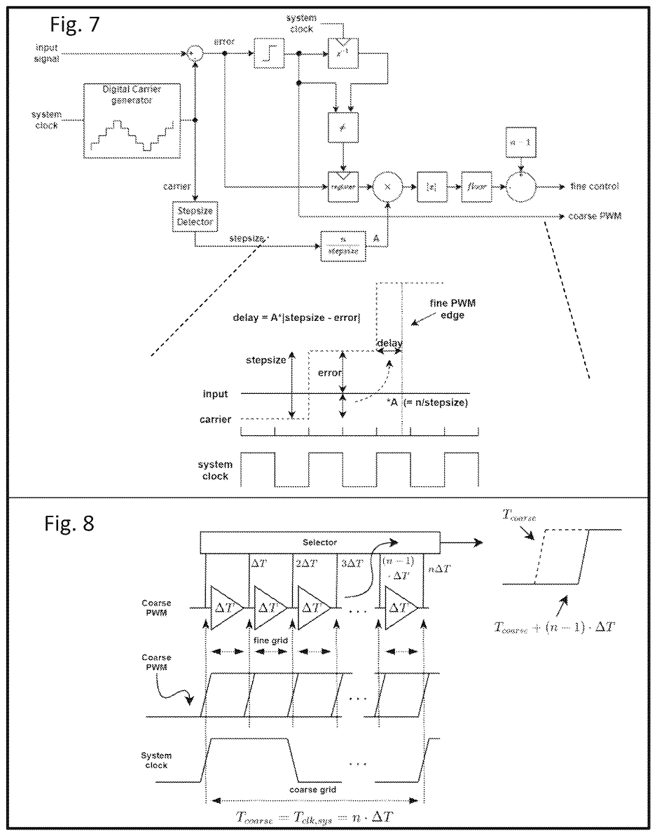

FIG. 7 (top) shows an example implementation of a digital PWM modulator with interpolation logic. FIG. 7 (bottom) shows an implementation example of the interpolation logic required to predict and select the correct delayed edge, based on the difference between the coarsely quantized PWM and the error signal from the digital PWM modulator. When an intersection occurs between the input signal and the carrier signal, a zero crossing can be detected in the error signal. The sign of the error signal is used to output a logic ‘1’ when positive or a logic ‘0’ when negative. As mentioned, the digital carrier generator provides and output signal to a step-size detector, which step-size detector is configured to provide output in the form of step-size, and likewise, division of n by step-size, to a multiplier, or likewise, to a divider for dividing the input*n by the step-size.

A circuit having a flip-flop in conjunction with an XOR gate can be used. The circuit generates an enable pulse to capture the digital value of the error signal in a register.
This captured error signal is converted to a fine control word by subtracting the captured error signal from the step-size of the digital carrier waveform generated by the system clock.
The result is normalized to the step-size and taking the absolute value thereof to obtain a value ranging from 0 up-to 1. This value is then multiplied by the number of fine quantized steps ‘n’ within a clock cycle of the system clock and floored to obtain an integer number ranging from 0 to n−1.

The mathematical operation is thus:

fine control=floor(n*abs((stepsize−error)/step-size))

Which can be rewritten to:

$$fine control = ( n - 1 ) - floor ( abs ( A * error ) )$$

wherein A=n/step-size

The extra ‘−1’ originates from moving n and the minus sign out of the mathematical floor operation. Note that the resulting delay of the fine-PWM edge relating to the coarse PWM edge is:

$$delay = n / stepsize * abs ( stepsize - error )$$

FIG. 8 shows an Interpolation of a coarse PMM signal using a delay-line and selector logic. FIG. 8 shows the operation of the interpolation in more detail. A delay-line of n elements, each providing a ΔT delay, is tuned such that the signal at the start of the delay-line and the end is matched with the coarse PWM grid, limited by the system clock rate, Because of the principle of interpolation, the coarse time step of the system clock is subdivided by n, equally timed steps of ΔT. The coarse PWM signal is presented to this delay-line, and based on the digital interpolation logic, one of these (delayed) paths is then selected, decreasing the minimal time steps of the PWM modulator and thus increasing the number of possible pulsewidths.

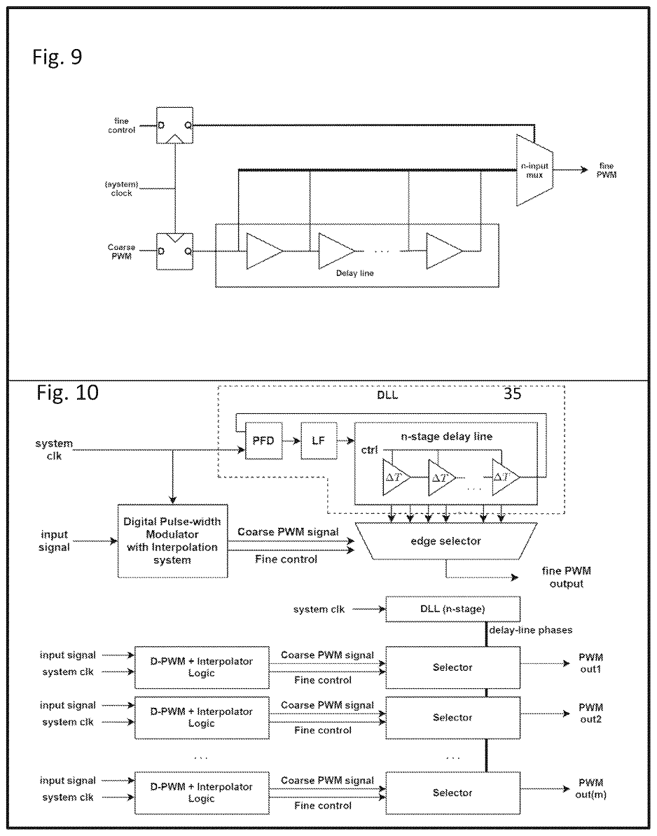

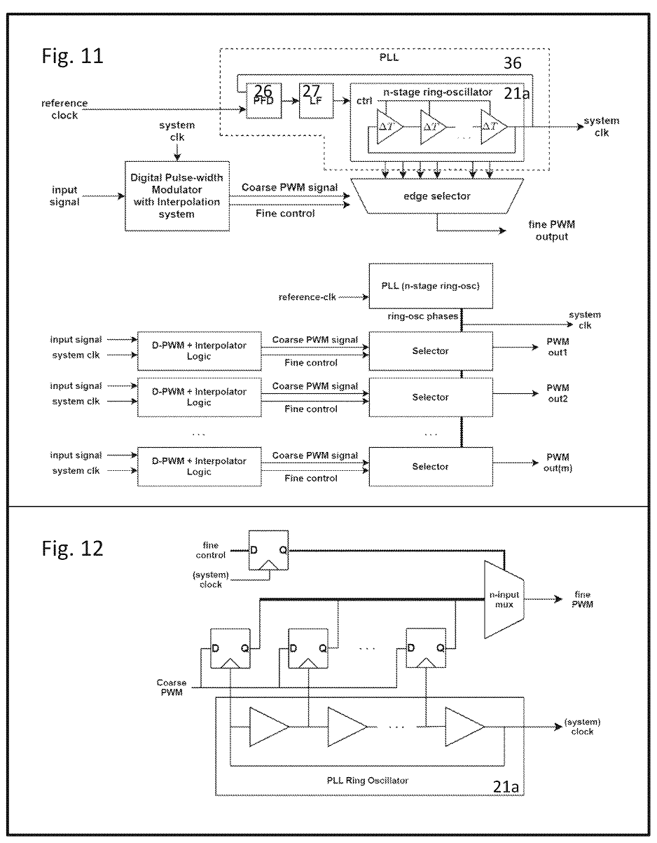

FIG. 9 shows an example of an ‘edge selector’ circuit. FIG. 9 shows an example of the edge-selector logic that can be used to select the correct delayed PWM signal based on a fine control code generated by the interpolation logic. The above invention can further be integrated with the use of a system-wide DLL or PLL (which is often already implemented on the IC), as shown in FIGS. 10 and 11 respectively. In this case, the coarse PWM signal is not used as the input for the delay line, but a more comprehensive edge selector is used, given that the delay-line or ring oscillator is locked to the same phase as the digital PWM modulator. Examples for these selector blocks are also given in FIG. 12.

FIG. 10 shows utilization of a single DLL locked on the system clock to generate nedges. Multiple (m) PWM subsystems can use the same edges for interpolation, proving the scalability of the solution.

FIG. 11 shows utilization of a single, ring-oscillator-based PLL as the source for interpolation edges, which can be utilized by multiple (m) PWM subsystems.

FIG. 12 shows an example of an edge-selector implementation given the use of a PLL ring oscillator as source for interpolation time grid.

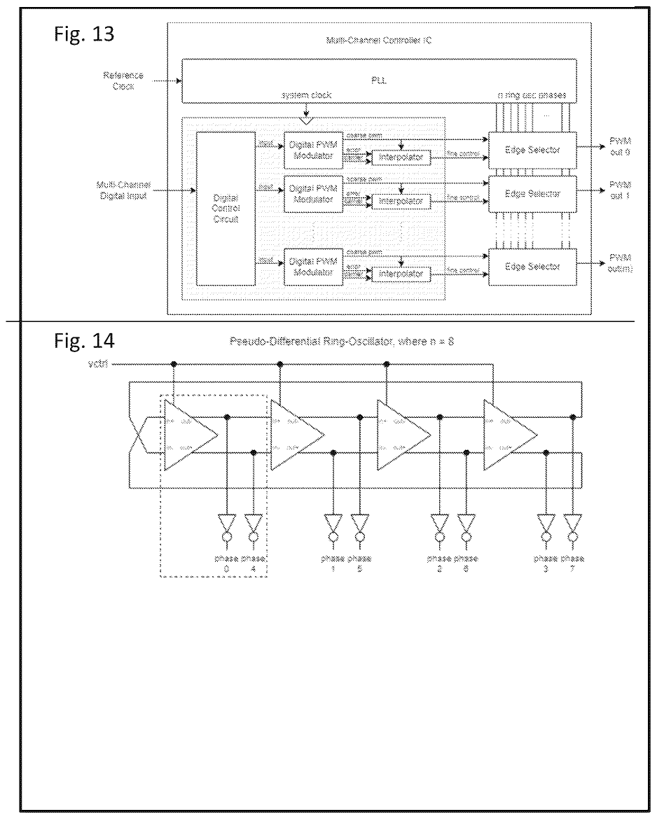

FIG. 13 shows an exemplary multi-channel controller. A reference clock input provides a clock signal to a PLL, of which a fine grid is provided to multiple edge selectors. A multi channel digital input, such as of an audio source, is provided to a digital control circuit, providing input to multiple DPWM modulators, receiving a clock signal from the PLL. The DPWM modulators each provide output to an interpolator, as is e.g. depicted in FIGS. 6 and 7. The interpolators each provide a fine control to each edge selector. Then, outputs PWM out m are provided.

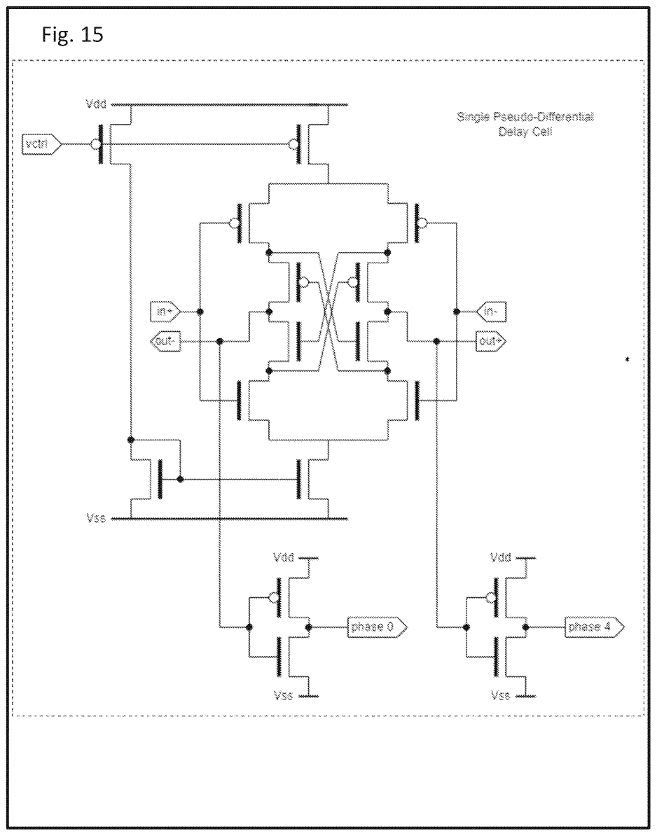

FIG. 14 shows an exemplary embodiment for a pseudo-differential ring-oscillator, with n=8. The pseudo-differential ring oscillator operates by means of a cascade of pseudo-differential delay cells, which can each output time-delayed versions of the input signal. This time-delay can be manipulated by a control signal such as ‘vctrl’. By cascading multiple delay cells as shown in the figure, and inversely connecting the outputs of the last delay cell to the first delay cell, an oscillating signal is generated during typical operation. Each output of the pseudo differential ring-oscillator contains a slightly delayed version of this oscillating signal. If the oscillating signal on one single output is considered as a ‘system clock’ on a coarse time grid, the plurality of other outputs can be considered as time delayed versions of the system clock yielding a fine time grid.

FIG. 15 shows an exemplary embodiment of a single pseudo-differential delay line cell, which may be referred to as a “Helleputte” cell. The cell can be described as a system of two coupled CMOS inverters, having two inputs (in+ and in−) and two outputs (out+ and out−). An inverter is a circuit of which the output is the logical inverse of the input. By means of coupling these inverters, their outputs will change state at the same time, even if the inputs are not switched at the same time. A time delay between the input and output of the coupled inverter is produced by limiting the speed at which the gate-source capacitance is charged or discharged. The series PMOS transistor that connects the coupled inverters to the supply regulates the rate of a rising output transition, and the series NMOS transistor between the coupled inverters and the ground regulates the rate of a falling output transition. The amount of regulation is controlled by manipulating the voltage on the ‘vctrl’ node. To limit the capacitive loading of the output nodes, which would impact the performance of the circuit, inverters are placed to isolate and buffer the signals used by other circuits such as an edge-selector.

1. Electronic circuit for pulse-width modulation comprising a clock generator configured to provide an operational clock speed for a coarse time grid, wherein the coarse time grid is provided to an input signal,
a Digital pulse-width modulator, the DPWM configured to receive input, and configured to provide output to a Delay-line and to an Interpolator of an interpolation circuit,
wherein the interpolation circuit-comprises
a Delay-line configured to provide output to an edge selector, wherein the DL comprises a delay controller configured to control the delay of the DL, and configured to provide output to an edge selector,
an Interpolator configured to receive input from the DPWM and from an error signal from the digital PWM modulator and to provide interpolated output to an edge selector, wherein the interpolator comprises a step-size detector configured to detect an increase in a carrier signal exceeding an input signal, and
an edge selector configured to provide time quantized PWM output.

2. Electronic circuit for pulse-width modulation according to claim 1, wherein the delay con-troller is configured to provide a delay locked loop with a DL fine quantized time grid, which DL fine time grid is N times smaller than the coarse time grid of the clock generator wherein N∈[2,210].

3. Electronic circuit for pulse-width modulation according to claim 1, wherein the DL is selected from an analog delay-line and a digital delay line.

4. Electronic circuit for pulse-width modulation according to claim 1, wherein the DL is configured to be controlled by a locked loop selected from a delay locked loop (DLL) and from a Phase Locked Loop (PLL).

5. Electronic circuit for pulse-width modulation according to claim 4, wherein the DL is part of a DLL, and wherein the DLL comprises a Phase Frequency Detector (PFD) configured to receive input from the clock generator and from the DL, a Loop Filter-configured to receive input from the PFD and to provide output to the DL.

6. Electronic circuit for pulse-width modulation according to claim 4, wherein the DL is part of a PLL, wherein the PLL comprises a Phase Frequency Detector-configured (PFD) to receive input from the clock generator and from the DL, a Loop Filter configured to receive input from the PFD and to provide output to the DL, wherein the DL's output is configured to feed back to its input therewith forming oscillator.

7. Electronic circuit for pulse-width modulation according to claim 6, wherein the oscillator and the clock generator are one and the same.

8. Electronic circuit for pulse-width modulation according to claim 1, comprising 2-M DPWMs wherein M∈[2,26].

9. Electronic circuit for pulse-width modulation according to claim 1, comprising one DL.

10. Electronic circuit for pulse-width modulation according to claim 1, comprising one edge selector.

11. Electronic circuit for pulse-width modulation according to any of claim 1, wherein the interpolator comprises a comparator configured for comparing the value of the carrier signal and the value of the input signal and providing an error signal, and a converter con-figured to convert the error signal into an integer value based on the number of quantized time grid elements and the error signal size and step-size.

12. Electronic circuit for pulse-width modulation according to claim 1, wherein the clock generator is configured to provide an operational clock speed of 5 MHz-20 GHz.

13. Electronic circuit for pulse-width modulation according to claim 1, further comprising a digital carrier generator configured to receive input from the clock generator, and an adder, configured to receive input from the digital carrier generator and to provide output to the Digital pulse-width modulator (DPWM) and to the Interpolator.

14. Delay-line for an electronic circuit, wherein the Delay-line is configured to pro-vide output to an edge selector, wherein the DL comprises a controller configured to control the delay of the DL and configured to provide output to the edge selector.

15. Pulse-width interpolator for an electronic circuit, wherein the interpolator is configured to provide interpolated output to the edge selector and to receive input from the Digital pulse-width modulator (DPWM) and from an error signal from the digital PWM modulator and to, comprising a step-size detector configured to detect an in-crease in a carrier signal exceeding an input signal, comprising a comparator configured for comparing the value of the carrier signal and the value of the input signal and providing an error signal, and a converter configured to convert the error signal into an integer value based on the number of quantized time grid elements and the error signal size and step-size

16. Integrated circuit comprising an electronic circuit according to claim 1, or a delay-line according to claim 14, or an interpolator according to claim 15.

17. Electronic device comprising an integrated circuit according to claim 16 or an electronic circuit according to claim 1, in particular wherein the electronic device is a product, wherein the product is selected from an audio amplifier, an active loudspeaker system, an active noise reduction system, a high-speed closed loop controller, a high resolution low latency data converter, an A/D converter, a power supply con-troller, an RF amplifier, a motor controller, in a high speed motor controller, an industrial controller, a microcontroller, a digital audio converter, a digital amplifier con-troller, and combinations thereof.

18. Electronic circuit for pulse-width modulation according to claim 6, wherein the oscillator is a stage ring-oscillator.
